(19) United States
(12) Patent Application Publication
(10) Pub. No.: US 2016/0238943 A1
(43) Pub. Date: Aug. 18, 2016

(54) PHOTORESIST STRIPPING METHOD AND APPARATUS

(71) Applicant: SHENZHEN CHINA STAR OPTOELECTRONICS TECHNOLOGY CO., LTD., Guangdong (CN)

(72) Inventor: Xudong ZHANG, Shenzhen, Guangdong (CN)

(73) Assignee: Shenzhen China Star Optoelectronics Technology Co., Ltd., Shenzhen, Guangdong (CN)

(21) Appl. No.: 14/381,912

(22) PCT Filed: Jul. 2, 2014
(86) PCT No.: PCT/CN2014/081432

§ 371 Date: Aug. 28, 2014

(30) Foreign Application Priority Data
Jun. 11, 2014 (CN) 201410259441.3

(51) Int. Cl. G03F 7/42; B08B 3/08; C11D 7/32; B08B 3/10; C11D 7/34; B08B 7/00; B08B 5/02

(52) U.S. Cl. CPC G03F 7/42; B08B 7/0057; B08B 3/08; B08B 5/02; B08B 3/102; C11D 7/34; C11D 7/3218

(57) ABSTRACT

The present invention provides a photoresist stripping method and photoresist stripping apparatus. The photoresist stripping method includes: step1, providing a substrate with a photoresist layer waiting for stripping; step 2, irradiating the photoresist layer waiting for stripping with an ultraviolet light; step 3, stripping the photoresist on a surface of the substrate by using a stripper in a stripping tank; step 4, removing the stripper remained on the substrate by using an air knife in a buffer area after stripping the photoresist; and step 5, washing out the stripper remained on the substrate in a water washing tank after blowing the air knife. The present invention greatly reduces corrosion on the aluminum and IGZO generated during the photoresist stripping process, and the quality of the flat panel display can be improved.

### FIELD OF THE INVENTION

The present invention relates to field of flat panel display processing, and more particularly to a photoresist stripping method and apparatus.

### BACKGROUND OF THE INVENTION

With quickly development of technology, the early display, cathode ray tube (Cathode Ray Tube, CRT), is developed to display nowadays, liquid crystal display (Liquid Crystal Display, LCD) and organic light emitting display (organic light emitting display, OLED).

The liquid crystal display has advantages of thin body, power saving, no radiation, etc., and is widely used. The liquid crystal displays on the market nowadays mostly are type of liquid crystal display with backlight, which includes a liquid display panel and a backlight module (backlight module). For fabricating a liquid crystal panel, there mainly includes three processes: “front-end array process”, “intermediate cell process”, and “back-end module assembly”. Wherein, the primary array process is to form the pre-designed ITO (Indium tin oxide) electrode pattern on a glass substrate; the intermediate cell process makes the TFT (thin film transistor) substrate and the CF (color filter) substrate be adhered to each other and injects liquid crystal materials there between to form the liquid crystal substrate; the back-end module assembly is to bonding the driver IC of the liquid crystal substrate and integrating the printed circuitry board. The front-end array process mainly includes four steps, “film forming”, “photolithography”, “etching” and “photoresist stripping”. Wherein, the step of photoresist stripping is generally to strip the photoresist layer (photoresist) remained after etching by using specialized stripping equipment and stripper.

The organic light emitting display has advantage of self-luminous, high brightness, high contrast, wide viewing angle, low driving voltage and fast response, etc., and is an important flat panel display in new generation displays. A common structure of OLED comprises a substrate, an ITO transparent anode disposed on the substrate, a hole injection layer disposed on the ITO transparent anode, a hole transport layer (HTL) disposed on the hole injection layer, an emission layer (EML) disposed on the hole transport layer, an electron transport layer (ETL) disposed on the emission layer, an electron injection layer (EIL) disposed on the electron transport layer, and a cathode disposed on the electron injection layer. While fabricating an OLED, the final step of semiconductor or photolithography process is photoresist stripping, which is to strip the photoresist used for protecting patterns in the previous step of etching, in order to prevent the photoresist from polluting the next photolithography process and obtain a clean substrate with patterns. If there is photoresist remained on the surface of the display panel, especially in the luminous area of the ITO anode, the subsequent deposited materials of organic light emitting layer and cathode are barred such that the defective pixels are generated, and the display quality and the process qualification ratio are lowered. Furthermore, since the subsequent deposited organic light emitting film is very thick such that the thickness difference due to the remained photoresist would result in uneven distributed electric field easily and even short-circuit device, and affecting life of the display thereby. Accordingly, stripping effect in the step of photoresist stripping plays an important influence in the OLED fabrication process.

When the substrate used in the liquid crystal display or OLED has aluminum layer or IGZO layer therein, a problem affecting the stripping effect of the step of photoresist stripping is that, the alkali substance, which is generated due to reaction occurred when the stripper contacts with water, would result in corrosion on the aluminum film or IGZO (indium gallium zinc oxide), such that Mura having shape of oblique strip waterlines which can be seen by eyes is generated when the produced liquid crystal layer display and organic light emitting display is lighted, and affects the quality of flat panel display thereby.

### SUMMARY OF THE INVENTION

An object of the present invention is to provide a photoresist stripping method for reducing corrosion on the aluminum and IGZO such that the defect occurred in fabrication of flat panel display can be reduced, and the quality of the flat panel display can be improved.

Another object of the present invention is to provide a photoresist stripping apparatus for greatly reducing corrosion on the aluminum and IGZO when processing photoresist stripping by adding a buffer area and setting up a plural air knives and an anti-liquid-splash guard in the buffer area such that the quality of the flat panel display can be improved.

To achieve the above objects, the present invention provides a photoresist stripping method, comprising the steps of:

Step1, providing a substrate with a photoresist layer waiting for stripping;

Step 2, irradiating the photoresist layer waiting for stripping with an ultraviolet light;

Step 3, stripping the photoresist on a surface of the substrate by using a stripper in a stripping tank;

Step 4, removing the stripper remained on the substrate by using an air knife in a buffer area after stripping the photoresist; and

Step 5, washing out the stripper remained on the substrate in a water washing tank after blowing the air knife.

Wherein the stripper includes 30 wt %-70 wt % monoethanolamine and 70 wt %-30 wt % dimethyl sulfoxide.

A transfer speed for transferring the substrate from the stripping tank to the water washing tank for washing out after completion of photoresist stripping is above 10000 mm/min, and the Step 4 is performed during transferring the substrate.

A plural air knives are used in the Step 4; two water washing tanks are used for washing out twice in the Step 5.

An anti-liquid-splash guard is set on the buffer area in the Step 4 in order to prevent the water washing tank in the Step 5 from being entered by the stripper in the stripping tank in the Step 3.

An exhausting pressure of the water washing tank is less than the exhausting pressure of the stripping tank to prevent evaporated stripper from entering the water washing tank.

Flow of washing out water is greater than 85 L/min, flow of water jet is greater than 40 L/min.

The substrate has an aluminum layer or an IGZO layer and is used in a liquid crystal display or an OLED.

The present invention further provides a photoresist stripping apparatus used for the above mentioned photoresist stripping method, comprising an entrance area, an ultraviolet irradiation unit, a first buffer area, a stripping tank, a second buffering area, a first water washing tank and a second water washing tank being placed in order, and further comprising a transferring unit for transferring a substrate sequentially from the entrance area through the ultraviolet irradiation unit, the first buffer area, the stripping tank, the second buffer area and the first water washing tank, and finally transferred to the second water washing tank.

The second buffer area is equipped with an anti-liquid-splash guard and a plural air knives.

The present invention further provides a photoresist stripping apparatus used for the above mentioned photoresist stripping method, comprising an entrance area, an ultraviolet irradiation unit, a first buffer area, a stripping tank, a second buffering area, a first water washing tank and a second water washing tank being placed in order, and further comprising a transferring unit for transferring a substrate sequentially from the entrance area through the ultraviolet irradiation unit, the first buffer area, the stripping tank, the second buffer area and the first water washing tank, and finally transferred to the second water washing tank;

wherein the second buffer area is equipped with an anti-liquid-splash guard and a plural air knives.

The beneficial effect of the present invention is: the photoresist stripping method and photoresist stripping apparatus greatly reduces the amount of stripper contacting with water in the water washing tank by adding a second buffer area between the stripping tank and the first water washing tank and setting a plural air knives for removing the strippers remained on the surface of the substrate; an anti-liquid-splash guard is further set in the second buffer area to prevent the stripper from entering into the first water washing tank; in the mean time, the transfer speed of transferring substrate by the transfer unit is improved such that the substrate leaves alkaline environment fast; exhausting pressure is adjusted such that the exhausting pressure of the water washing tank is less than the exhausting pressure of the stripping tank to prevent evaporated stripper from entering the water washing tank which results in generating alkali substance. Corrosion on the aluminum and IGZO occurred in photoresist stripping can be reduced by technical means described above, and the quality of the flat panel display can be improved. In the mean time, the process of the photoresist stripping is simple and is easily operated. The structure of the photoresist apparatus is simple, and the quality of the fabricated flat panel display is improved and the fabrication cost is lowered.

Please refer to the detailed description and the attached drawings for further understanding the feature and technique content of the present invention. The attached drawings are only for providing reference and explanation but not for limiting the present invention.

### BRIEF DESCRIPTION OF THE DRAWINGS

The technique contents and other beneficial effects of the present invention will become more readily apparent to those ordinarily skilled in the art through detailed description with accompanying drawings.

In the drawings:

FIG. 1 is a flow chart of the photoresist stripping method of the present invention.

FIG. 2 is a schematic diagram of the photoresist stripping apparatus of the present invention.

### DETAILED DESCRIPTION OF PREFERRED EMBODIMENTS

In order to more specifically describe the technical means and the effects of the present invention, the best embodiments and drawings are described in detail as follows.

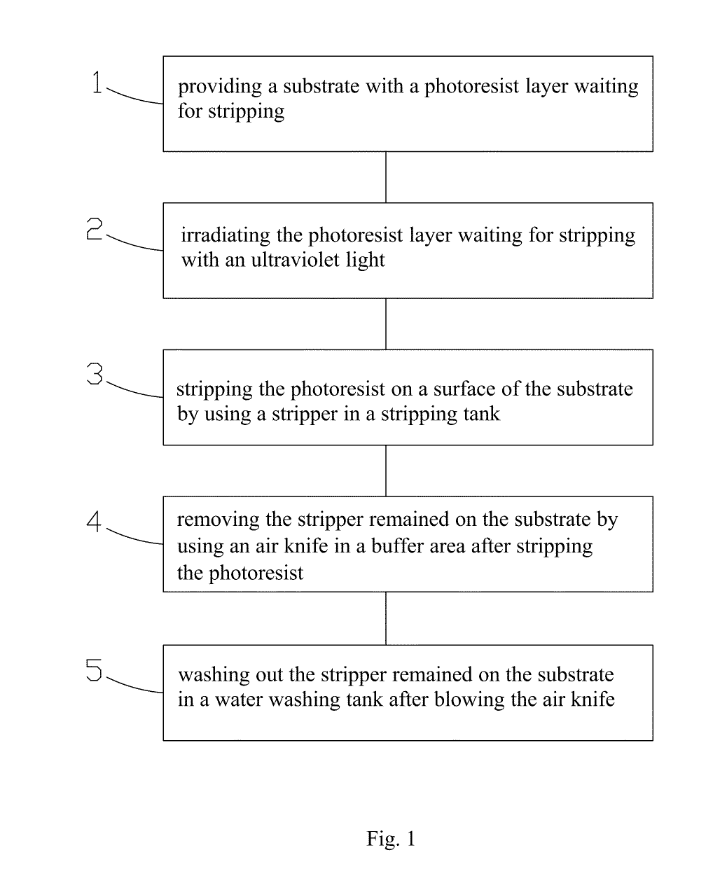

Please refer to FIG. 1. The present invention provides a photoresist stripping method, which comprises the steps of:

Step1, providing a substrate with a photoresist layer waiting for stripping;

Step 2, irradiating the photoresist layer waiting for stripping with an ultraviolet light;

Step 3, stripping the photoresist on a surface of the substrate by using a stripper in a stripping tank;

Step 4, removing the stripper remained on the substrate by using an air knife in a buffer area after stripping the photoresist; and

Step 5, washing out the stripper remained on the substrate in a water washing tank after blowing the air knife.

The stripper includes 30 wt %-70 wt % monoethanolamine and 70 wt %-30 wt % dimethyl sulfoxide. Because the monoethanolamine and the dimethyl sulfoxide are organic substances, the hydroxide therein falls off and dissolved in water to produce alkali substances when they meet with a great amount of water such that the IGZO or aluminum is corroded.

A transfer speed for transferring the substrate from the stripping tank to the water washing tank for washing out after completion of photoresist stripping is above 10000 mm/min in order to leave alkaline environment fast such that corrosion on the aluminum or IGZO can be reduced, and the Step 4 is performed during transferring the substrate.

A plural air knives are used in the Step 4. The air knife has an upper metal knife face and a lower metal knife face, uniform wind is generated by passing into ultra-pure air to perform liquid-removing operation for the surface of the substrate. The amount of stripper contacting with water can be greatly reduced by setting a plural air knives, and therefore generation of alkali substances is reduced.

An anti-liquid-splash guard is set on the buffer area in the Step 4 in order to prevent the water washing tank in the Step 5 from being entered by the stripper in the stripping tank in the Step 3.

Two water washing tanks are used for washing out twice in the Step 5 in order to completely remove strippers remained on the substrate. The wash-out liquid in the water washing tanks is deionized water.

An exhausting pressure of the water washing tank is less than the exhausting pressure of the stripping tank to prevent evaporated stripper from entering the water washing tank.

Flow of washing out water is controlled to be greater than 85 L/min and flow of water jet is controlled to be greater than 40 L/min in the water washing tank in order to reduce the time the substrate contacting with the alkaline substances such that corrosion on the aluminum or IGZO can be reduced.

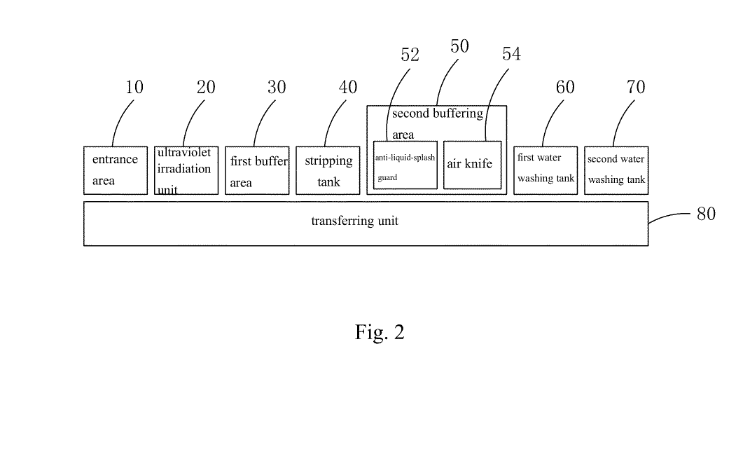

Please refer to FIG. 2. The present invention provides a photoresist stripping apparatus used in the above described photoresist stripping method. The photoresist stripping apparatus comprises an entrance area 10, an ultraviolet irradiation unit 20, a first buffer area 30, a stripping tank 40, a second buffering area 50, a first water washing tank 60 and a second water washing tank 70 being placed in order, and further comprises a transferring unit 80 for transferring a substrate (not shown) sequentially from the entrance area 10 through the ultraviolet irradiation unit 20, the first buffer area 30, the stripping tank 40, the second buffer area 50 and the first water washing tank 60, and finally transferred to the second water washing tank 70.

The second buffer area 50 is equipped with an anti-liquid-splash guard 52 and a plural air knives 54. The anti-liquid-splash guard 52 can prevent the first water washing tank 60 and the second water washing tank 70 from being entered by the stripper in the stripping tank 40.

Wash-out liquid is sprayed on the substrate in the first water washing tank 60 and the second water washing tank 70, and the wash-out liquid is deionized water.

Accordingly, in order to achieve the subject of removing the photoresist, the photoresist stripping method and photoresist stripping apparatus of the present invention irradiates the photoresist layer by ultraviolet light, and then stripping the irradiated photoresist by using strippers, and removing the stripper remained on the surface of the substrate by using wash-out liquids; the amount of stripper contacting with water in the water washing tank is greatly reduced by adding a second buffer area between the stripping tank and the first water washing tank and setting a plural air knives for removing the strippers remained on the surface of the substrate; an anti-liquid-splash guard is further set in the second buffer area to prevent the stripper from entering into the first water washing tank; in the mean time, the transfer speed of transferring substrate by the transfer unit is improved such that the substrate leaves alkaline environment fast; exhausting pressure is adjusted such that the exhausting pressure of the water washing tank is less than the exhausting pressure of the stripping tank to prevent evaporated stripper from entering the water washing tank which results in generating alkali substance. Corrosion on the aluminum and IGZO occurred in photoresist stripping can be reduced by technical means described above, and the quality of the flat panel display can be improved. In the mean time, the process of the photoresist stripping is simple and is easily operated. The structure of the photoresist apparatus is simple, and the quality of the fabricated flat panel display is improved and the fabrication cost is lowered.

Those with ordinary skill in the art are capable of make various modifications and arrangements in accordance to the technical solutions and technical ideas of the present invention, and those modifications and arrangements should be covered by the scope of the appended claims of the present invention.

What is claimed is:

1. A photoresist stripping method, comprising the steps of:
Step1, providing a substrate with a photoresist layer waiting for stripping;
Step 2, irradiating the photoresist layer waiting for stripping with an ultraviolet light;
Step 3, stripping the photoresist on a surface of the substrate by using a stripper in a stripping tank;
Step 4, removing the stripper remained on the substrate by using an air knife in a buffer area after stripping the photoresist; and
Step 5, washing out the stripper remained on the substrate in a water washing tank after blowing the air knife.

2. The photoresist stripping method of claim 1, wherein the stripper includes 30 wt %-70 wt % monoethanolamine and 70 wt %-30 wt % dimethyl sulfoxide.

3. The photoresist stripping method of claim 1, wherein a transfer speed for transferring the substrate from the stripping tank to the water washing tank for washing out after completion of photoresist stripping is above 10000 mm/min, and the Step 4 is performed during transferring the substrate.

4. The photoresist stripping method of claim 1, wherein a plural air knives are used in the Step 4; two water washing tanks are used for washing out twice in the Step 5.

5. The photoresist stripping method of claim 1, wherein an anti-liquid-splash guard is set on the buffer area in the Step 4 in order to prevent the water washing tank in the Step 5 from being entered by the stripper in the stripping tank in the Step 3.

6. The photoresist stripping method of claim 1, wherein an exhausting pressure of the water washing tank is less than the exhausting pressure of the stripping tank to prevent evaporated stripper from entering the water washing tank.

7. The photoresist stripping method of claim 1, wherein flow of washing out water is greater than 85 L/min, flow of water jet is greater than 40 L/min.

8. The photoresist stripping method of claim 1, wherein the substrate has an aluminum layer or an IGZO layer and is used in a liquid crystal display or an OLED.

9. A photoresist stripping apparatus for the photoresist stripping method of claim 1, comprising an entrance area, an ultraviolet irradiation unit, a first buffer area, a stripping tank, a second buffering area, a first water washing tank and a second water washing tank being placed in order, and further comprising a transferring unit for transferring a substrate sequentially from the entrance area through the ultraviolet irradiation unit, the first buffer area, the stripping tank, the second buffer area and the first water washing tank, and finally transferred to the second water washing tank.

10. The photoresist stripping apparatus of claim 9, wherein the second buffer area is equipped with an anti-liquid-splash guard and a plural air knives.

11. A photoresist stripping apparatus for the photoresist stripping method of claim 1, comprising an entrance area, an ultraviolet irradiation unit, a first buffer area, a stripping tank, a second buffering area, a first water washing tank and a second water washing tank being placed in order, and further comprising a transferring unit for transferring a substrate sequentially from the entrance area through the ultraviolet irradiation unit, the first buffer area, the stripping tank, the second buffer area and the first water washing tank, and finally transferred to the second water washing tank;
wherein the second buffer area is equipped with an anti-liquid-splash guard and a plural air knives.
